(19) United States
(12) Patent Application Publication
(10) Pub. No.: US 2005/0076272 A1
(43) Pub. Date: Apr. 7, 2005

(54) Unequal error protection using forward error correction based on reed-solomon codes

(75) Inventors: Gilles Delmas, Epinay-Sous-Senart Franc (FR); Christophe Samson, Paris (FR)

Correspondence Address: PHILIPS INTELLECTUAL PROPERTY & STANDARDS, P.O. BOX 3001, BRIARCLIFF MANOR, NY, 10510, US

(73) Assignee: Koininklijke Philipd Electronics N.V., BA Eindhoven (NL)

(21) Appl. No.: 10/499,941

(22) PCT Filed: Dec. 18, 2002
(86) PCT No.: PCT/IB02/05620

(30) Foreign Application Priority Data
Dec. 28, 2001 (EP) 01403386.4

(51) Int. Cl. G06F 11/00; H03M 13/00

(52) U.S. Cl. 714/701; 714/784

(57) ABSTRACT

The invention proposes a new scheme for unequal error protection using forward error correction based on Reed-Solomon codes. The invention applies to data packets comprising data symbols having various level of importance. It consists in applying a single RS code to all data symbols regardless of their level of importance, but in skipping one or more of the error correction symbols generated from the data symbols of lower importance when forming error correction packets, if reduction of the redundancy is necessary.

### FIELD OF THE INVENTION

The invention deals with a method for protecting data packets against transmission errors, said data packets comprising data symbols having various levels of importance.

It also deals with a program comprising instructions for implementing such a method.

The invention further deals with a transmission system comprising a transmitter and a receiver, said transmitter being intended for transmitting data packets, said data packets comprising data symbols having various levels of importance.

It also deals with a device intended for transmitting data packets comprising data symbols having various levels of importance.

The invention further deals with a signal transporting data packets and error correction packets.

The invention is especially useful in the area of video transmission via network prone to congestion, like the Internet, and/or via networks prone to transmission errors, like mobile radio networks.

### BACKGROUND OF THE INVENTION

The Internet draft standard “An RTP Payload Format for Erasure-Resilient Transmission of Progressive Multimedia Streams” published by the IETF under reference “draft-ietf-avt-uxp-01.txt” and expiring in May 2002 describes an unequal error protection strategy for progressively encoded source stream. The aim of the proposed strategy is to reduce the overhead due to redundancy. The described strategy consists in partitioning the data into different classes, and applying a different Reed-Salomon code for each class in order to generate a different number of error correction symbols for each class.

Such a strategy is complex to implement especially at the receiver side. One of the object of the invention is to propose an unequal error protection strategy for encoded source streams which is less complex to implement.

### SUMMARY OF THE INVENTION

This is achieved with a method for protecting data packets against transmission errors as claimed in claim 1, a transmission system as claimed in claim 5, a device intended for transmitting data packets as claimed in claim 7, a program as claimed in claim 9 and a signal transporting data packets and error correction packets as claimed in claim 10.

According to the invention a same error correction code is used to generate all the error correction symbols regardless of the level of importance of the data symbols from which they are generated. But one or more of the level of importance of the data symbols from which they are generated. But one or more of the error correction symbols generated from the data symbols having a low level of importance are not transmitted when the overhead due to redundancy is to be restricted.

In other words, when the overhead due to redundancy is to be restricted, the invention introduces initial symbols losses before transmission. This means that the invention does not use the whole capacity of the error correction code for the data symbols having a low level of importance.

Generally speaking using a single error correction code is advantageous because it simplifies the implementation at the transmitter side and at the receiver side.

The invention is particularly advantageous when a Reed-Salomon (RS) error correction code is used because RS error correction codes are very costly in terms of calculation power. The invention allows to combine the use of RS codes and unequal error protection without increasing the complexity of the receiver. Such combined use of RS codes and unequal error protection is especially interesting when high quality transmission is expected over Internet and/or mobile radio networks.

The invention is of particular interest for mobile receivers because limitation of the required calculation power leads to energy savings.

Advantageously said selection step depends on the current state of said network, for example on the current packet error rate of the transmission network.

### BRIEF DESCRIPTION OF THE DRAWINGS

FIG. 1 is a schematic diagram showing a transmission system according to the invention.

FIG. 2 is a diagram explaining how error correction symbols and error correction packets are generated according to the invention, when using a RS error correction code.

FIG. 3 is a block diagram of forward error correction means according to the invention.

FIG. 4 is a diagram describing an implementation of the invention for video packets encoded by using the data partitioning mode of the MPEG-4 standard.

### DESCRIPTION OF THE INVENTION

The delivery of data over packets switched networks is prone to error. In wired networks such as the Internet, traffic congestion induces packets losses. In wireless networks such as UMTS or GPRS networks, fading, noise and interferences generate bit errors at the receiver, and one wrong bit in a packet induces a loss of the whole packet when CRC mechanisms (Cyclic Redundancy Check) are used.

Retransmission of lost packets is not always suitable or possible, especially for real-time applications such as audio/video conversational applications.

Forward Error Correction (FEC) is a known solution to protect data against errors. FEC consists in adding redundancy to the original data prior to transmission. The added redundancy is used at the receiver for recovering lost packets.

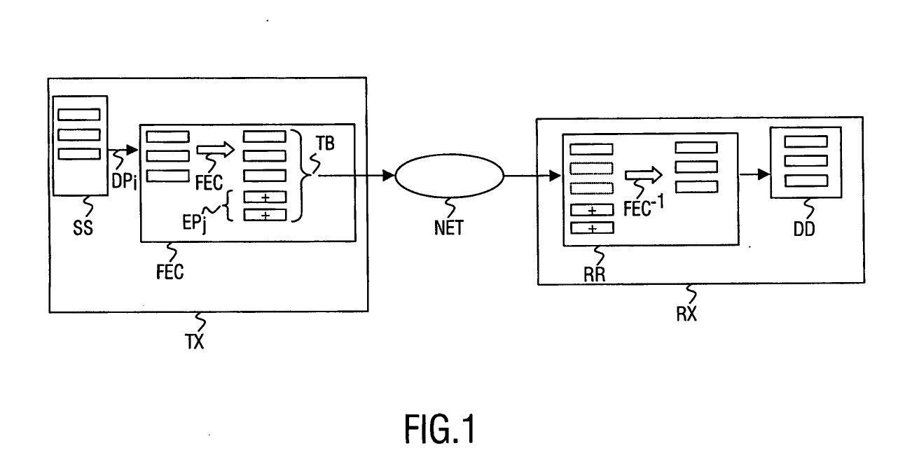

An example of a transmission system using FEC is shown in FIG. 1. With reference to FIG. 1, a transmitter TX comprises a data source SS for delivering data packets DPᵢ, and forward error correction means FEC for generating error correction packets EPⱼ from the data packets DPᵢ. For instance the data source SS is an MPEG-4 encoder. The data packets DPᵢ together with their associated error correction packets EPⱼ form a transmission block TB. Transmission blocks are transmitted over a transmission network NET to a receiver RX. The receiver RX comprises data packets recovery means RR for recovering the data packets lost during the transmission (second and third data packets in FIG. 1). Said data packets recovery means RR deliver the received data packets and the recovered data packets to a data destination DD (for instance an MPEG-4 decoder).

Forward error correction means use an error correction code. Reed-Salomon RS codes are well known to be powerful and flexible codes. An RS correction code is defined by two parameters n and k. Basically an RS (n, k) correction code consists in constructing code words of n symbols from data words of k symbols (which means that n-k redundant symbols are added for each data word of k symbols). In the following, the added redundant symbols are called error correction symbols. An RS (n, k) code can correct up to t errors and p erasures (an erasure being an error of known position) such that 2t+p=n-k.

In a FEC transmission scheme using a RS (n, k) correction code, a transmission block consists in k data packets and (n-k) error correction packets obtained by applying the RS (n, k) correction code to the k data packets.

The invention applies to data packets comprising data symbols having at least two levels of importance (or in which at least two levels of importance can be established) so that it is possible to associate different levels of protection to the data symbols depending on their level of importance. For seek of simplicity the example described below is directed to data symbols having two levels of importance high importance or low importance). This is not restrictive.

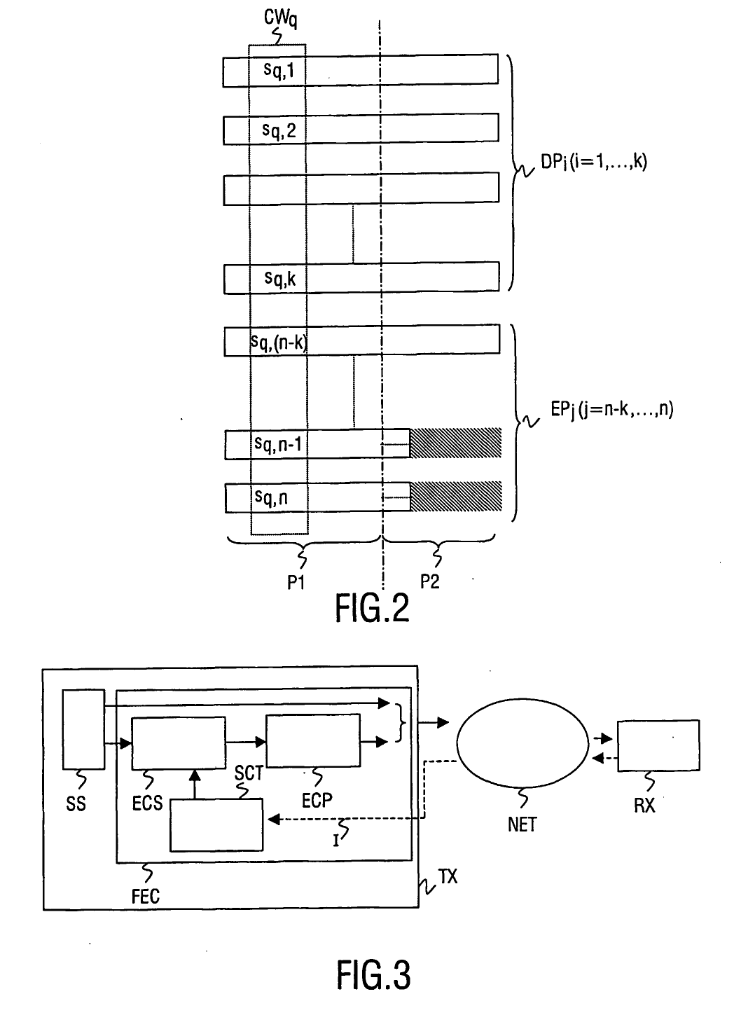

FIG. 2 gives a representation of how error correction symbols and error correction packets are generated according to the invention. A transmission block TB comprises k data packets DPᵢ (i=1, . . . , k) and (n-k) error correction packets EPⱼ (j=n−k, . . . , n). A doted line L represents a separation between a first partition P1 and second partition P2 of data symbols. The first partition P1 comprises the data symbols having a high importance. Partition P1 will receive a higher protection. The second partition P2 comprises the data symbols having a low importance. Partition P2 will receive a lower protection. The location of the doted line L depends on the required level of protection. For a given RS (n, k) code, the biggest the ratio P1/P2 the highest the protection.

A single RS (n, k) code is used to generate a set of (n-k) error correction symbols (s_{q, (n-k)}, . . . s_{q, n}) for each set of k data symbols (s_{q, l}, . . . S_{q, k}) of same rank q (q=1, . . . , m where m is an integer) in said k data packets regardless of the partition the data symbols belong to. A set of k data symbols (s_{q, l}, . . . . S_{q, k}) and the corresponding set of (n-k) error correction symbols (s_{q, (n-k)}, . . . s_{q, n}) constitute a code word CW_{q} of n symbols.

Then (n-k) error correction packets are generated, each error correction packet being generated from the m error correction symbols (s_{i,j}, . . . sₘⱼ) where j=n-k, . . . , n.

According to the invention, one or more of the error correction symbols generated from data symbols of partition P2 are not inserted in one or more of the error correction packets, at least when the overhead due to redundancy is to be restricted. In the example described on FIG. 2, the error correction symbols generated from data symbols of partition P2 are not inserted in error correction packets EPₙ and EPₙ₋₁, which means that packets EPₙ and EPₙ₋1 are shorter.

FIG. 3 gives a schematic block diagram of forward error correction means according to the invention. With reference to FIG. 3, forward error correction symbol means FEC according to the invention comprise error correction generation means ECS controlled by selection means SCT, and error correction packets generation means ECP. The error correction generation means ECS generate error correction symbol as described with reference to FIG. 2. Selection means SCT are provided for selecting the error correction symbols to be inserted in error correction packets in view of the transmission of said error correction packets over the transmission network.

In an advantageous embodiment, the selection means SCT are responsive to information I received from the receiver RX through the network (via RTCP protocol for instance) so that the selection is adapted to the current state of the transmission network. For example, the receiver sends information relating to the error rate, and the selection is adapted so that the quantity of redundancy increases with the error rate. For instance, this may be achieved by shifting the doted line L or by modifying the number of error correction packets in which error correction symbols are missing.

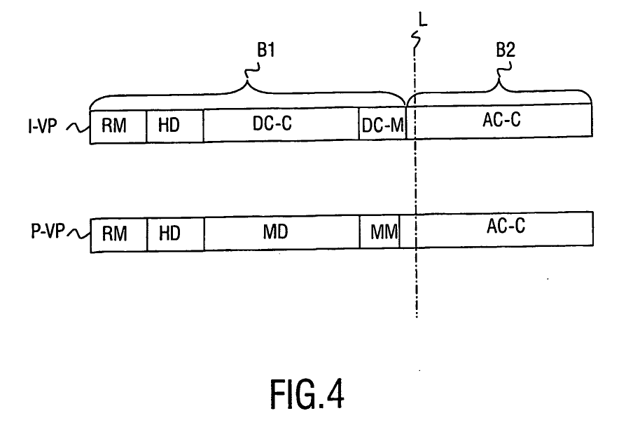

For example the invention applies to video packets encoded by using the data partitioning mode (DP) of the MPEG-4 standard. FIG. 4 gives a representation of such video packets for both the Intra encoding mode (mode for coding parameters that does not make reference to previously coded parameters to perform encoding) and the Inter encoding mode (mode for coding parameters that uses previously coded parameters to construct a prediction). Referring to FIG. 4, I-VP designates a video packet relating to a frame encoded with the Intra mode while P-VP designates a video packet relating to a frame encoded with Inter mode.

Both types of video packets contain a first block B1 and a second block B2. For I-VP video packets, the first block B1 contains:
resynchronisation markers RM,
a header HD,
the DC coefficients DC-C of the DCT (Discrete Cosine Transform),
and a DC marker DC-M.

For P-VP video packets, the first partition P1 contains:
resynchronisation markers RM,
a header HD,
motion data MD,
and a motion marker MM.

The second block B2 of I-VP and P-VP packets contain the AC coefficients AC-C of the DCT.

The data contained in the first block B1 are more important from a decoding point of view than the data contained in the second block B2. Indeed, the decoder is unable to decode a video packet when data are missing in the header or when motion data are missing. But if data are missing in block B2 it will still be able to decode the video packet.

With such MPEG-4 video packets, the doted line L of FIG. 2 is located for instance in such a way that all B1 blocks fully belong to partition P1. As the length of blocks B1 and B2 is unconstrained, the location of the doted line L is advantageously calculated for each transmission block. Therefore all data packets of the transmission block TB have to be parsed to retrieve the end of block B1 in each packet. As the end of blocks B1 are not always byte aligned, the doted line L is located at the end of the byte in which the longest block B1 terminates.

Such MPEG-4 video packets have a variable size smaller than a defined maximum size. Therefore, before the RS encoding, padding bits are added at the end of the MPEG-4 video packets having a size smaller than said defined maximum size. Advantageously said padding bits are not transmitted over the network, but the number of added padding bits is transmitted for each data packet. The receiver RX adds the transmitted number of padding bits for each received data packet before applying the RS decoding.

For instance, the data packets and the error correction packets are transmitted by using the Real Time Transfer Protocol (RTP). In such a case, the data packets are advantageously built as described in the RFC 1889 of the IETF. By way of example, the error correction packets are built as described in the IETF draft “An RTP payload format for Reed Solomon codes” from J. Rosenberg and H. Shulzrinne proposed on Nov. 3^{rd}, 1998 and expired on May 2^{nd}, 1999.

1. A method for protecting data packets against transmission errors, said data packets (DPᵢ) comprising data symbols (s_{qj} j=1, . . . k) having various levels of importance, said method comprising:
an error correction symbols generation step for generating error correction symbols (s_{qj}j=n-k, . . . , n) from said data symbols, regardless of the level of importance of said data symbols, by using an error correction code (RS(n, k)),
an error correction packets generation step for generating error correction packets (EPj) from said error correction symbols,
a selection step for selecting the error correction symbols to be included in said error correction packets depending on the level of importance of the data symbols from which said error correction symbols were generated.

2. A method as claimed in claim 1, characterized in that said error correction packets generation step is intended for generating (n-k) error correction packets from k data packets, an error correction symbol of rank q in an error correction packet being generated from the k data symbols of rank q in said k data packets, and in that said selection step allows not to include at least the error correction symbols generated from data symbols having the lowest level(s) of importance in at least one of said (n-k) error correction packets.

3. A method as claimed in claim 1, intended to be used for transmission over a network having a variable state, characterized in that said selection step depends on the current state of said network.

4. A method as claimed in claim 1, characterized in that said error correction code is a systematic block code.

5. A transmission system comprising a transmitter (TX) and a receiver (RX), said transmitter being intended for transmitting data packets (DPᵢ), said data packets comprising data symbols (s_{qj}j=1, . . . k) having various levels of importance, said transmitter comprising:
error correction symbols generation means for generating error correction symbols (s_{qj} j=n-k, . . . , n) from said data symbols, regardless of the level of importance of said data symbols, by using an error correction code (RS(n, k)),
error correction packets generation means for generating error correction packets (EPⱼ) from said error correction symbols,
selection means for selecting the error correction symbols to be included in said error correction packets depending on the level of importance of the data symbols from which said error correction symbols were generated.

6. A transmission system as claimed in claim 5, characterized in that said error correction packets generation means are intended for generating (n-k) error correction packets from k data packets, an error correction symbol of rank q in an error correction packet being generated from the k data symbols of rank q in said k data packets, and in that said selection step allows not to include at least the error correction symbols generated from data symbols having the lowest level(s) of importance in at least one of said (n-k) error correction packets.

7. A device (TX) intended for transmitting data packets (DPᵢ) comprising data symbols (S_{qj}j=1, . . . k) having various level of importance, said transmitter comprising:
error correction symbols generation means for generating error correction symbols (S_{qj}j=n-k, . . . , n) from said data symbols, regardless of the level of importance of said data symbols belong to, by using an error correction code,
error correction packets generation means for generating error correction packets (EPⱼ) from said error correction symbols,
selection means for selecting the error correction symbols to be included in said error correction packets depending on level of importance of the data symbols from which said error correction symbols were generated.

8. A device as claimed in claim 7, characterized in that said error correction packets generation means are intended for generating (n-k) error correction packets from k data packets, an error correction symbol of rank q in an error correction packet being generated from the k data symbols of rank q in said k data packets, and in that said selection means allow not to include at least the error correction symbols generated from data symbols having the lowest level(s) of importance in at least one of said (n-k) error correction packets.

9. A program comprising instructions for implementing a method as claimed in claim 1, when executed by a processor.

10. A signal transporting data packets and error correction packets wherein:
a set of (n-k) error correction packets correspond to a set of k data packets,
said data packets comprise data symbols having various levels of importance,
said error correction packets comprise error correction symbols, an error correction symbol of rank q in a set of (n-k) error correction packets being generated from the k data symbols of rank q in the corresponding k data packets by using an error correction code,
at least one of the error correction symbols generated by said error correction code from data symbols having the lowest level(s) of importance being missing in at least one of said error correction packets.
